(19) United States
(12) Patent Application Publication
(10) Pub. No.: US 2026/0324456 A1
(43) Pub. Date: Oct. 15, 2026

(54) FAN-OUT SYSTEM-IN-PACKAGE STRCURE AND MANUFACTURING METHOD

(71) Applicant: SJ Semiconductor(Jiangyin) Corporation, Jiangyin (CN)

(72) Inventors: Yenheng CHEN, Jiangyin (CN); Chengchung LIN, Jiangyin (CN)

(73) Assignee: SJ Semiconductor(Jiangyin) Corporation, Jiangyin, JS (CN)

(21) Appl. No.: 19/108,443

(22) PCT Filed: Jun. 1, 2023
(86) PCT No.: PCT/CN2023/097799

§ 371 Date: Mar. 4, 2025

(30) Foreign Application Priority Data
Sep. 5, 2022 (CN) 202211075889.0

(51) Int. Cl. H10W 70/60; H10W 40/00; H10W 40/20; H10W 70/00; H10W 70/05; H10W 70/06; H10W 70/63; H10W 72/00; H10W 74/15; H10W 90/00; H10W 90/10; H10W 90/22

(52) U.S. Cl. CPC H10W 70/614; H10W 40/03; H10W 40/233; H10W 40/242; H10W 70/06; H10W 70/095; H10W 70/099; H10W 70/635; H10W 90/10; H10W 90/22; H10W 90/736; H10W 72/877; H10W 74/15; H10W 90/724

(57) ABSTRACT

A fan-out system level packaging structure and a method are disclosed. The method includes: providing a support carrier, forming a first rewiring layer, a metal connecting post, and a second rewiring layer, forming a conducting bump electrically connected to the first rewiring layer, providing a first functional chip and a component electrically connected to the second rewiring layer respectively, and providing an encapsulated wafer to connect the conducting bump. The technique interconnects of the upper and lower layers through metal connection columns, and connects the first function chip and components on the second rewiring layer to make high-density connection. It can connect the second function chip and connectors via the electrically conducting bumps. The system can integrate processor, memory and other function chips and optoelectronic components, optical components and MEMS components all in an encapsulated wafer. The high-density hermetically sealed interconnections increase flexibility, compatibility, and packaging performance.

### TECHNICAL FIELD

The present invention belongs to the field of semiconductor packaging and relates to a fan-out system level packaging structure and a method of making the same.

### BACKGROUND

With the progress of science and technology, the miniaturization and multi-fictionization of electronic end products have become a major trend of industries. To integrate and package several different kinds of high-density chips together to form a powerful system or subsystem in a small volume with low power consumption has become a major challenge in the field of advanced semiconductor chip packaging.

The constant demand for higher functionality, better performance, higher energy efficiency, lower manufacturing cost and smaller size has led to the emergence of some advanced packaging technologies such as chip-scale packaging (CSP), wafer-level packaging (WLP) and system-in-package (SIP). System level packaging technology as an emerging heterogeneous integration technology, has been applied in more and more chips in the form of packaging. System level packaging enables a variety of functions of the chips and components integrated in a package, so as to achieve basic complete functions, a short development cycle, more functions, lower power consumption, better performance, smaller size, light weight and other advantages. However, with the increasing demand for packaging components and functions, the existing system-level packaging also suffers from defects such as poor integration, poor compatibility, and small degree of integration, unable to meet the demand for ultra-high density packaging.

### SUMMARY

The present invention provides a fan-out system level package structure and a production method for integrating multiple functional chips and components in a single encapsulated wafer, which can be used to solve the problems of poor integration, poor compatibility, and small degree of integration of system level packages in the existing technique.

The present invention provides a method of fabricating a fan-out system level packaging structure comprising the following steps:
providing a support carrier and forming a separation layer on the support carrier;
forming a first rewiring layer on the separation layer, the first rewiring layer comprising a laminated first dielectric layer and a first metal wiring layer;
forming a metal connection post on the first rewiring layer, the metal connection post being electrically connected to the first metal wiring layer;
forming an encapsulation layer over the first rewiring layer, the encapsulation layer covering the first rewiring layer and the metal connection post, and thinning the encapsulation layer to reveal the metal connection post;
forming a second rewiring layer on the encapsulation layer, the second rewiring layer comprises a second dielectric layer and a second metal wiring layer stacked, the second metal wiring layer is electrically connected to the metal connection post;
peeling the support carrier by the separation layer to expose a side of the first rewiring layer away from the encapsulation layer;
forming an electrically conducting bump on a side of the first rewiring layer away from the encapsulation layer, the electrically conducting bump is electrically connected to the first rewiring layer;
providing at least one first functional chip with at least one component, electrically connecting the first functional chip and the component respectively to a side of the second rewiring layer away from the encapsulation layer;
forming a cooling layer on the second rewiring layer, forming a cavity between the cooling layer and the second rewiring layer, and the first function chip and the components are located in the cavity; and
providing an encapsulated wafer and connecting the conducting bump to the encapsulated wafer.

Optionally, prior to forming the metal connecting post, there is further included the step of forming a first opening in the first rewiring layer on a side of the first rewiring layer away from the separating layer, the first opening revealing the first metal wiring layer, the metal connecting post extending into the first opening to connect with the first metal wiring layer.

Optionally, prior to forming the electrically conducting bump, the step of forming a second opening in the first rewiring layer on a side of the first rewiring layer away from the encapsulation layer is also included, the second opening revealing the first metal wiring layer, and the electrically conducting bump extending into the second opening to connect with the first metal wiring layer.

Optionally, the number of the first function chips is a plurality, the plurality of the first function chips being arranged in an array in the horizontal direction; the number of the components is a plurality, the plurality of the components being arranged in an array in the horizontal direction.

Optionally, the first rewiring layer comprises at least one the first dielectric layer and at least one the first metal wiring layer stacked in a vertical direction; the second rewiring layer comprises at least one the second dielectric layer and at least one the second metal wiring layer stacked in a vertical direction.

Optionally, the providing an encapsulated wafer, prior to connecting the conducting bump to the encapsulated wafer, further comprises the steps of:

Providing at least one second function chip, connecting the second function chip to the conducting bump;

A connector is provided connecting the connector to the conducting bump, the second functional chip being spaced a predetermined distance from the connector, wherein the conducting bump is connected to the encapsulated wafer through the connector.

The present invention also provides a fan-out system level packaging structure comprising:
a first rewiring layer, the first rewiring layer comprising a laminated first dielectric layer and a first metal wiring layer;
a second rewiring layer, disposed above the first rewiring layer and spaced a predetermined distance from the first rewiring layer, the second rewiring layer comprising a second dielectric layer and a second metal wiring layer;
an encapsulation layer disposed between the first rewiring layer and the second rewiring layer;
a metal connecting post, running in a vertical direction through the encapsulation layer, the bottom end of the metal connecting post being electrically connected to the first metal wiring layer and the top end of the metal connecting post being electrically connected to the second metal wiring layer;
an electrically conducting bump, disposed below the first rewiring layer, the electrically conducting bump being electrically connected to the first rewiring layer;
at least one first function chip, the first function chip being electrically connected to the second rewiring layer;
at least one component, the component being electrically connected to the second rewiring layer, the component being spaced a predetermined distance from the first functional chip;
a cooling layer, disposed on the second rewiring layer, the cooling layer forming a cavity between the cooling layer and the second rewiring layer, the first functional chip and the components being disposed in the cavity; and
an encapsulated wafer, located on a side of the first rewiring layer having the conducting bumps, the encapsulated wafer being connected to the conducting bumps.

Optionally, the number of the first function chips is a plurality, the plurality of the first function chips being arranged in an array in the horizontal direction; the number of the components is a plurality, the plurality of the components being arranged in an array in the horizontal direction.

Optionally, the first rewiring layer comprises at least one the first dielectric layer and at least one the first metal wiring layer stacked in a vertical direction; the second rewiring layer comprises at least one the second dielectric layer and at least one the second metal wiring layer stacked in a vertical direction.

Optionally, the encapsulated wafer and the conducting bump further comprises a connector and at least one second function chip between the encapsulated wafer and the conducting bump, the connector being connected to the conducting bump, the second function chip being connected to the conducting bump and the second function chip being spaced at a predetermined distance from the connector, wherein the encapsulated wafer is connected to the conducting bump via the connector.

As mentioned above, in the fan-out system level packaging structure and production method of the present invention, the interconnection of the upper and lower layers is realized through metal connection columns, which can be used for ultra-high-level process system level packaging, and the first functional chips and components are connected to the second rewiring layer for high-density connectivity packaging, which enables the integration of processors, memories, and other functional chips, as well as photovoltaic components, optics, and MEMS components, etc., into a basic and complete function in a single encapsulated wafer (e.g., 8-inch or 12-inch). MEMS components, etc. can be integrated in a package to realize a basic complete function, which not only improves the integration of process structure, but also helps to reduce the package size. And a second functional chip can be attached to the conducting bump to improve flexibility and compatibility while realizing a high-density hermetic connection and increasing the performance of the package body.

### BRIEF DESCRIPTION OF THE DRAWINGS

FIG. 1 shows a process flow diagram of a method of fabricating a fan-out type system level package structure of the present invention.

FIG. 2 shows a schematic diagram of a method of fabricating a fan-out type system level packaging structure of the present invention in which a support carrier is provided and a separation layer is formed on the support carrier.

FIG. 3 shows a schematic diagram of forming a first rewiring layer on the separation layer and forming a first opening in a method of fabricating a fan-out type system level package structure of the present invention.

FIG. 4 shows a schematic diagram of forming a metal connection post on the first rewiring layer in a method of fabricating a fan-out type system level package structure of the present invention.

FIG. 5 shows a schematic diagram of forming an encapsulation layer on the first rewiring layer in a method of fabricating a fan-out type system level package structure of the present invention.

FIG. 6 shows a schematic diagram of thinning the encapsulation layer in a method of fabricating a fan-out type system level package structure of the present invention.

FIG. 7 shows a schematic diagram of forming a second rewiring layer on the encapsulation layer in a method of fabricating a fan-out type system level package structure of the present invention.

FIG. 8 shows a schematic diagram of a method of fabricating a fan-out system level package structure of the present invention in which the support carrier is removed based on the separation layer to reveal the first rewiring layer.

FIG. 9 shows a schematic diagram of forming a second opening on a side of the first rewiring layer away from the encapsulation layer in a method of fabricating a fan-out type system level package structure of the present invention.

FIG. 10 shows a schematic diagram of forming a conducting bump on a side of the first rewiring layer away from the encapsulation layer in a method of fabricating a fan-out type system level encapsulation structure of the present invention.

FIG. 11 shows a schematic diagram of a method of fabricating a fan-out system level package structure of the present invention in which a first functional chip and a component are provided, connecting the first functional chip and the component, respectively, to the second rewiring layer.

FIG. 12 shows a schematic diagram of forming a first filler layer at a connection gap between the first functional chip and the second rewiring layer in a method of fabricating a fan-out type system level package structure of the present invention.

FIG. 13 shows a schematic diagram of forming a cooling layer on the second rewiring layer in a method of fabricating a fan-out type system level package structure of the present invention.

FIG. 14 shows a plan view of the first functional chip and the components in a fan-out system level package structure of the present invention.

FIG. 15 shows a schematic diagram of a method of making a fan-out type system level package structure of the present invention in which a second function chip and a connector are provided and the second function chip and the connector are connected to the conducting bumps, respectively.

### REFERENCE NUMERALS

10—support carrier, 20—separation layer, 30—first rewiring layer, 31—first dielectric layer, 32—first metal wiring layer, 301—first opening, 302—second opening, 40—metal connecting post, 50—encapsulation layer, 60—second rewiring layer, 61—second dielectric layer, 62—second metal wiring layer, 70—conducting bump, 80—first function chip, 81—chip pads, 90—components, 100—first filler layer, 110—cooling layer, 120—thermal transfer medium layer, 130—second function chip, 140—connector, 150—second filler layer, S1~S10—steps.

### DETAILED DESCRIPTION OF THE PREFERRED EMBODIMENTS

Embodiments of the present invention are hereinafter described by way of particular specific examples, and other advantages and efficacies of the present invention can be readily appreciated by those skilled in the art from what is disclosed in this specification. The present invention may also be implemented or applied in different other specific embodiments, and various details in this specification may also be modified or changed in various ways based on different views and applications without departing from the spirit of the present invention.

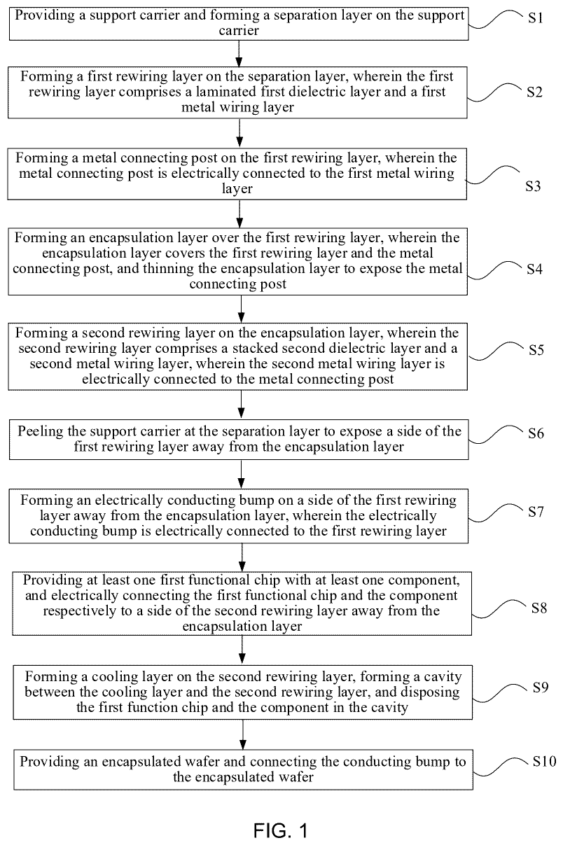

Refer to FIGS. 1 through 15. It is to be noted that the illustrations provided in this embodiment only illustrate the basic concept of the present invention in a schematic manner, and only the components related to the present invention are shown in the illustrations, which are not drawn in accordance with the number, shape, and size of the components in actual implementation, and the actual implementation of the components, the number, and the proportion of the components may be changed arbitrarily, and the layout of the components may also be more complex.

### Embodiment 1

This embodiment provides a method of fabricating a fan-out system level packaging structure, refer to FIG. 1, showing a process flow diagram of the method, comprising the following steps:
S1: Providing a support carrier, forming a separation layer on the support carrier;
S2: forming a first rewiring layer on the separation layer, the first rewiring layer comprising a laminated first dielectric layer and a first metal wiring layer;
S3: forming a metal connection post on the first rewiring layer, the metal connection post being electrically connected to the first metal wiring layer;
S4: forming an encapsulation layer over the first rewiring layer, the encapsulation layer covering the first rewiring layer and the metal connection post, and thinning the encapsulation layer to reveal the metal connection post;
S5: forming a second rewiring layer on the encapsulation layer, the second rewiring layer comprising a stacked second dielectric layer and a second metal wiring layer, the second metal wiring layer being electrically connected to the metal connecting post;
S6: peeling the support carrier based on the separation layer to expose a side of the first rewiring layer away from the encapsulation layer;
S7: forming an electrically conducting bump on a side of the first rewiring layer away from the encapsulation layer, the electrically conducting bump being electrically connected to the first rewiring layer;
S8: providing at least one first functional chip with at least one component, electrically connecting the first functional chip and the component to a side of the second rewiring layer away from the encapsulation layer, respectively;
S9: A cooling layer is formed on the second rewiring layer, a cavity is formed between the cooling layer and the second rewiring layer, and the first function chip and the components are located in the cavity;
S10: Providing an encapsulated wafer, connecting the conducting bump to the encapsulated wafer.

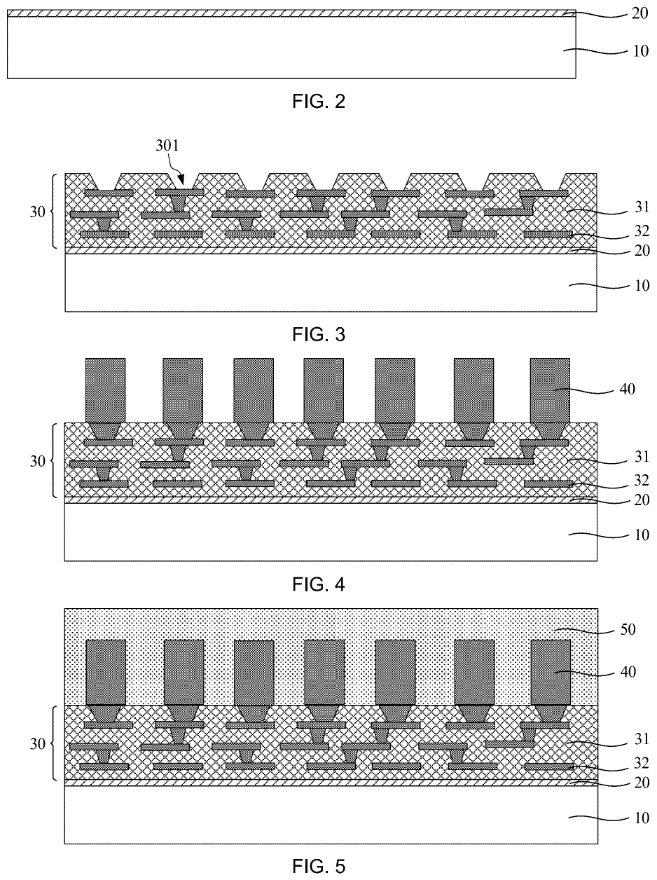

First, referring to FIG. 2, step S1 is performed: a support carrier 10 is provided and a separation layer 20 is formed on the support carrier 10.

As an example, the support carrier 10 includes, but is not limited to, any one of a glass carrier, a metal carrier, a semiconductor carrier, a polymer carrier, and a ceramic carrier for preventing cracking, warping, fracturing, etc., of the layer structure during encapsulation, and the shape of the support carrier 10 may be wafer-like, panel-like, and any other desired shape. In this embodiment, the support carrier 10 is made of a glass carrier, which is less costly, can easily form the separation layer 20 on its surface, and can reduce the difficulty of the subsequent stripping process.

As an example, the material of the separation layer 20 comprises a tape or a polymer, which is applied to the surface of the support carrier 10 by a spin-coating process and then molded by UV curing or heat curing.

Referring to FIG. 3, step S2 is then performed: forming a first rewiring layer 30 on the separation layer 20, the first rewiring layer 30 comprising a laminated first dielectric layer 31 and a first metal wiring layer 32.

As an example, the step of forming the first rewiring layer 30 comprises:
(1) A first dielectric layer 31 is formed on the surface of the separation layer 20 using chemical vapor deposition, physical vapor deposition, or other suitable method, the first dielectric layer 31 being made of a material including, but not limited to, one or a combination of two or more of epoxy resin, silicone, PI, PBO, BCB, silicon oxide, phosphor-silicon glass, fluorine-containing glass;
(2) Forming a first metal layer on the surface of the first dielectric layer 31 using sputtering, electroplating, chemical plating, or other suitable methods, and etching the first metal layer to form a patterned first metal wiring layer 32. The material of the first metal wiring layer 32 includes one or a combination of two or more of copper, aluminum, nickel, gold, silver, or titanium.

It is noted that the above steps may be repeated as necessary to form the first rewiring layer 30 having a multilayered stacked structure for different wiring needs, with the multilayered first metal wiring layer 32 being electrically connected to each other by electrically conductive plugs.

As an example, a first opening 301 is formed on a side of the first rewiring layer 30 away from the separation layer 20 to reveal the first rewiring layer 32, the method of forming the first opening 301 comprising photolithographic etching, laser perforation, or other suitable method, and the first opening 301 is progressively enlarged in a funnel-like shape from the bottom up.

Referring to FIG. 4, step S3 is then performed: a metal connection post 40 is formed on the first rewiring layer 30, the metal connection post 40 being electrically connected to the first metal wiring layer 32.

As an example, the metal connection post 40 extends into the first opening 301 to connect with the first metal wiring layer 32.

As an example, the method of forming the metal connecting post 40 comprises electroplating, chemical plating, wire bonding or other suitable method, the material of the metal connecting post 40 comprises one or a combination of two or more of copper, aluminum, nickel, gold, silver, titanium, with electroplated copper posts being preferred in this embodiment.

It is noted that on the surface of the first rewiring layer 30 directly forming the metal connecting post 40 without any obstruction, without worrying about adverse effects on other structures during fabrication, and can be realized in conjunction with the first metal rewiring layer 32 The alignment with the first metal wiring layer 32 can be realized, which greatly simplifies the process compared to the conventional method of forming a dielectric layer first and then forming through holes in the dielectric layer and then depositing the metal, and can realize a fine line and wide line spacing layout, which is conducive to high-density connection.

Step S4 is then performed: forming an encapsulation layer 50 on the first rewiring layer 30, the encapsulation layer 50 covering the first rewiring layer 30 and the metal connecting post 40, and thinning the encapsulation layer 50 to reveal the metal connecting post 40.

As an example, the encapsulation layer 50 is formed on the first rewiring layer 30 as shown in FIG. 5, the method of forming the encapsulation layer 50 includes, but is not limited to, any of compression molding, transfer molding, liquid sealing molding, vacuum lamination, and spin-coating, and the material of the encapsulation layer 50 comprises a curable material such as a polymer-based material, a resin-based material, a polyamide, and any combination thereof.

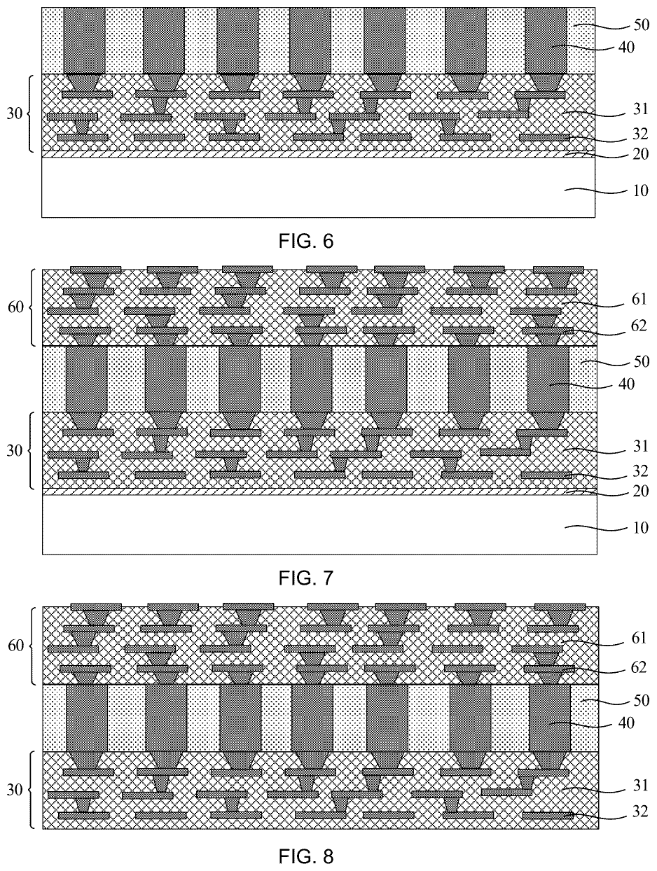

As an example, the encapsulation layer 50 is thinned to reveal the metal connecting post 40 as shown in FIG. 6, the method of thinning the encapsulation layer 50 comprising grinding, polishing, or other suitable method, the upper surface of the encapsulation layer 50 after thinning being flush with the upper surface of the metal connecting post 40.

Referring to FIG. 7, step S5 is then performed: a second rewiring layer 60 is formed on the encapsulation layer 50, the second rewiring layer 60 comprising a stacked second dielectric layer 61 and a second metal wiring layer 62, the second metal wiring layer 62 being electrically connected to the metal connecting post 40.

As an example, the method of forming the second rewiring layer 60 is the same as the method of forming the first rewiring layer 30, and is not described in detail herein.

Referring to FIG. 8, step S6 is then performed: peeling off the support carrier 10 based on the separation layer 20 to expose a side of the first rewiring layer 30 away from the encapsulation layer 50.

Specifically, depending on the type of the separating layer 20 a corresponding method is used to make the separating layer 20 less sticky and thus peel off the support carrier 10 and the separating layer 20. For example, when the separation layer 20 is made of a photo-thermal conversion material, a laser may be used to irradiate the photo-thermal conversion layer to separate the photo-thermal conversion layer from the first rewiring layer 30 and the support carrier 10.

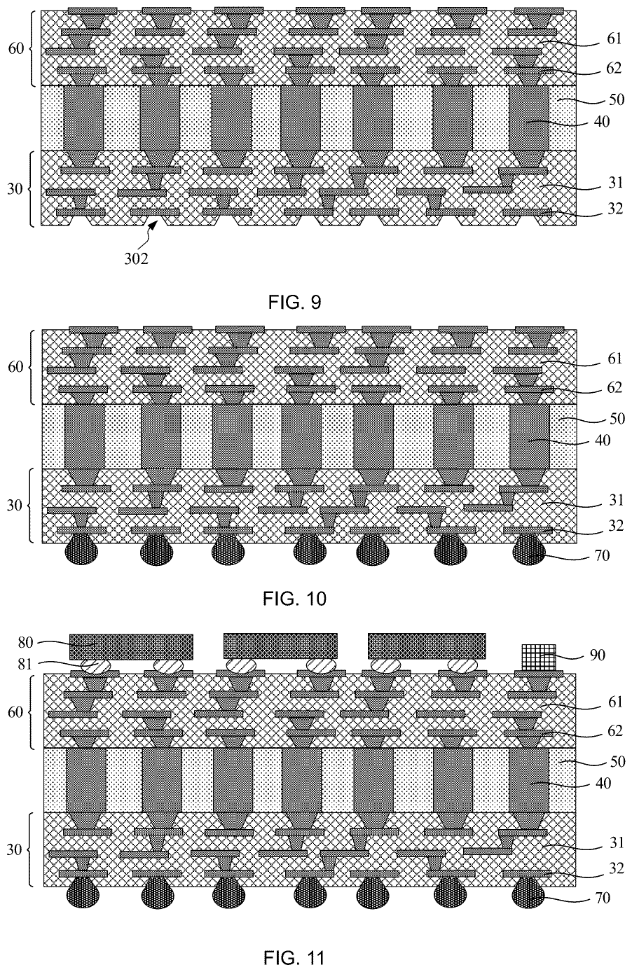

As an example, as shown in FIG. 9, a second opening 302 is formed on a side of the first rewiring layer 30 away from the encapsulation layer 50 to reveal the first rewiring layer 32; the method of forming the second opening 302 includes photolithographic etching, laser perforation, or other suitable method, and the second opening 302 tapers from the bottom to the top in an inverted funnel shape.

Referring to FIG. 10, step S7 is then performed: a conducting bump 70 is formed on a side of the first rewiring layer 30 away from the encapsulation layer 50, the conducting bump 70 being electrically connected to the first rewiring layer 32.

As an example, the conducting bump 70 extends into the second opening 302 to connect with the first metal wiring layer 32, and the conducting bump 70 may comprise a metal post, a solder joint, or may simply be a solder ball.

Referring to FIG. 11, step S8 is then performed, providing at least one first function chip 80 with at least one component 90, electrically connecting the first function chip 80 and the component 90, respectively, to a side of the second rewiring layer 60 away from the encapsulation layer 50.

As examples, the first functional chip 80 has a plurality of numbers, the types of which include processors, memories and the like, and the components 90 have a plurality of numbers, the types of which include optoelectronic components, optical components and MEMS components and the like. It is to be noted that the present embodiment only exemplarily enumerates several types of the first function chip 80 and the components 90, and is not limited by the present embodiment, and in the actual production and manufacturing, the types and quantities of the first function chip 80 and the components 90 are selected according to the functional requirements of the encapsulated body.

Specifically, the first functional chip 80 is electrically connected to the second rewiring layer 60 via chip pads (chip pins) 81 and the components 90 are connected to the second rewiring layer 60 via Surface Mounted Technology (SMT).

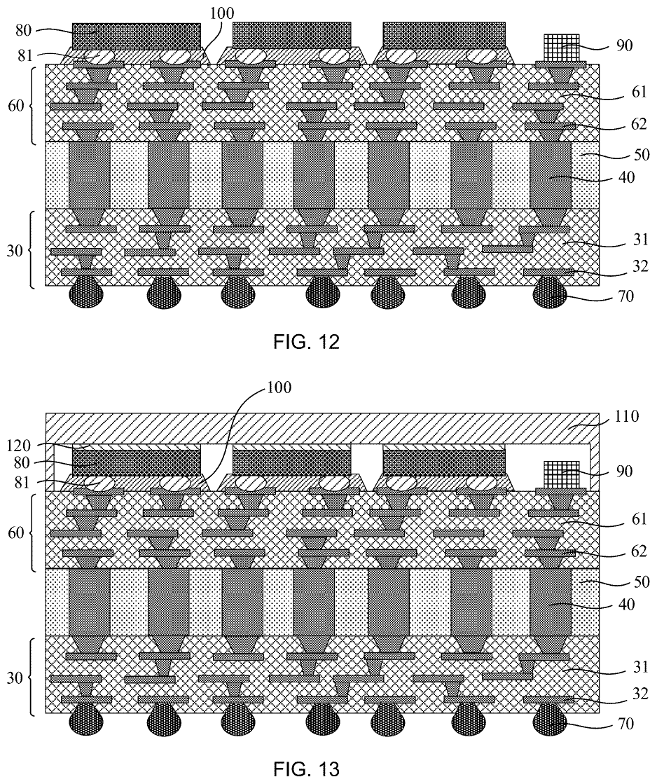

As an example, as shown in FIG. 12, a first filler layer 100 may be further formed at the connection gap between the first function chip 80 and the second rewiring layer 60 by using a dispensing process or other suitable process, the first filler layer 100 may on the one hand provide protection against corrosion or connection damage to the connection between the first function chip 80 and the second rewiring layer 60, and On the other hand, it can improve the bonding properties between the first function chip 80 and the second rewiring layer 60 and improve the mechanical strength.

Referring to FIG. 13, step S9 is then performed: a cooling layer 110 is formed on the second rewiring layer 60, a cavity is formed between the cooling layer 110 and the second rewiring layer 60, and the first function chip 80 and the component 90 are both located in the cavity.

As an example, the material of the cooling layer 110 comprises one of silver, copper, gold and aluminum, or may be other suitable high thermal conductivity material.

As an example, a heat transfer medium layer 120 is formed between the surface of the first function chip 80 and the cooling layer 110, the heat transfer medium layer 120 may be a thermal paste or other highly thermally conductive material, so that on the one hand, said heat transfer medium layer 120 may act as a binder between the first function chip 80 and the cooling layer 110, and on the other hand, heat from the first function chip 80 may be more effectively thermally transferred to the cooling layer 110 through the first function chip 80. heat from the first function chip 80 can be more efficiently thermally transferred to the cooling layer 110 via said heat transfer medium layer 120.

Next, step S10 is performed: providing an encapsulated wafer, connecting the conducting bump 70 to the encapsulated wafer.

As an example, the encapsulation wafer comprises an 8-inch or 12-inch encapsulation wafer, specifically, in this embodiment, the encapsulation wafer adopts a 12-inch encapsulation wafer, and the conducting bump 70 is connected to the encapsulation wafer for subsequent electrical lead-in to the encapsulation body, such as connection to an external power supply and the like.

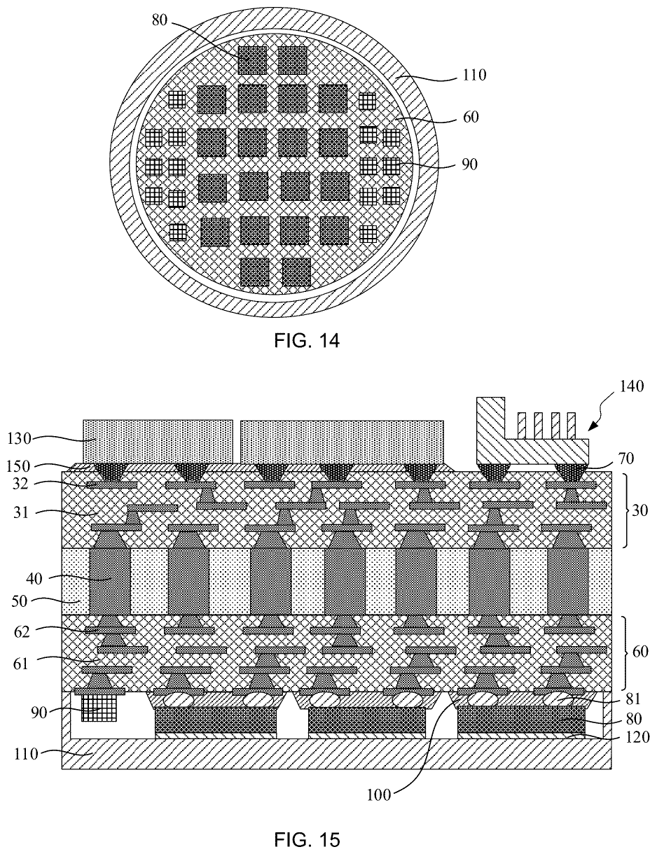

As an example, as shown in FIG. 14, shown as a plan view of a planar layout of the first function chip 80 and the components 90, a plurality of the first function chips 80 and a plurality of the components 90 are arranged in an array, which allows for the integration of a plurality of function chips, including a processor, a memory, etc., and a plurality of components, including photovoltaic components, optical components, MEMS components, etc., in a single encapsulated wafer in a single package in a single encapsulated wafer, thereby realizing a substantially complete function.

Optionally, as shown in FIG. 15, a second function chip 130 and a connector 140 are provided to connect the second function chip 130 and the connector 140, respectively, to the conducting bump 70.

As an example, the second function chip 120 includes, but is not limited to, a processor, a memory, a power management chip, a transmitter chip, a receiver chip, and the like.

As an example, a second filler layer 150 is formed at the connection gap between the second function chip 130 and the electrically conducting bump 70, the second filler layer 150 can, on the one hand, provide protection for the connection between the second function chip 130 and the electrically conducting bump 70, preventing corrosion or damage to the connection, and, on the other hand, can improve the bonding property of the second function chip 150 and the electrically conducting bump 70 to improve mechanical strength. performance and improve the mechanical strength.

As an example, the connector 140 comprises a header connector, the connector 140 being used to subsequently connect to the encapsulated wafer and thus to an external power supply.

It should be noted that by providing two chip layers (i.e., a first function chip 80 layer area and a second function chip 130 layer area), higher flexibility and wider compatibility are achieved while realizing a high-density sealed connection. For example, realizing the complete function of the package body while setting up two chip layers can improve the spacing between the chips, reduce the crosstalk between the chips, and improve flexibility and compatibility.

In the fabrication method of the fan-out system level packaging structure provided in this embodiment, the interconnection of the upper and lower layers is realized by metal connecting columns, which enables ultra-high-level process system level packaging, and the first function chip and components are connected to the second rewiring layer to make a high-density hermetic connection package, which enables the processor, the memory and other function chips, and the optoelectronic components, optical components, and the MEMS components, etc., to be integrated into one encapsulated wafer to realize a basically complete function. A package body to achieve a basic complete function, can improve the integration of the process structure, reduce the size of the package; in addition, the conducting bumps can be connected to the second function chip and connectors, in order to realize high-density sealed connection at the same time, with higher flexibility and wider compatibility, increase the performance of the package body.

### Embodiment 2

Referring to FIG. 13, the present embodiment provides a fan-out type system level packaging structure, the fan-out type system level packaging structure may be fabricated by the fabrication method described in Example 1, but is not limited to the fabrication method described in Example 1.

The fan-out system level packaging structure includes a first rewiring layer 30, a second rewiring layer 60, a packaging layer 50, a metal connecting post 40, a conducting bump 70, at least one first functional chip 80, at least one component 90, a cooling layer 110, and a packaging wafer, wherein the first rewiring layer 30 comprises a stacked first dielectric layer 31 and a first metal wiring layer 32, the second rewiring layer 60 is disposed above the first rewiring layer 30 and spaced apart from the first rewiring layer 30 by a predetermined distance, the second rewiring layer 60 comprises a laminated second dielectric layer 61 and a second metal wiring layer 62, the encapsulation layer 50 is disposed between the first rewiring layer 30 and the second rewiring layer 60, and the metal connecting post 40 extends vertically through the encapsulation layer 50, the bottom end of the metal connecting post 40 being electrically connected to the first metal wiring layer 32, the top end of the metal connecting post 40 being electrically connected to the second metal wiring layer 62, the electrically conducting bump 70 being disposed underneath and electrically connected to the first rewiring layer 30, the first functional chip 80 being electrically connected to the second rewiring layer 60, the component 90 is electrically connected to the second rewiring layer 60, the component 90 being spaced apart from the first function chip 80 by a predetermined distance, the cooling layer 110 being disposed on the second rewiring layer 60, the cooling layer 110 forming a cavity between the cooling layer 110 and the second rewiring layer 60, the first function chip 80 and the component 90 being disposed in the cavity, and the encapsulated wafer located on a side of the first rewiring layer 60 having the conducting bumps 70, the encapsulated wafer being connected to the conducting bumps 70.

As an example, the first rewiring layer 30 comprises at least one of the first media layer 31 and at least one of the first metal wiring layer 32 stacked in a vertical direction, and the second rewiring layer 60 comprises at least one second dielectric layer 61 and at least one second metal wiring layer 62 stacked in a vertical direction.

As an example, the encapsulation layer 50 includes, but is not limited to a polymer-based material layer, a resin-based material layer, a polyamide layer, an epoxy resin layer, and any combination thereof.

By way of example, the metal connecting posts 40 include, but are not limited to, copper posts.

As an example, the electrically conducting bump 70 may comprise a metal post, a solder joint, or may simply be a tin ball.

As examples, the first functional chip 80 has a plurality of numbers, the types of which include processors, memories and the like, and the components 90 have a plurality of numbers, the types of which include optoelectronic components, optical components and MEMS components and the like. It is to be noted that the present embodiment only exemplarily enumerates several types of the first function chip 80 and the components 90, and is not limited by the present embodiment, and in actual application, the types and numbers of the first function chip 80 and the components 90 are selected according to the functional requirements of the encapsulated body.

As an example, the first function chip 80 comprises a chip pad 81, the first function chip 80 being electrically connected to the second metal wiring layer 62 via the chip pad 81.

As an example, a first filler layer 100 is provided at the connection gap between the first function chip 80 and the second rewiring layer 60, the first filler layer 100 can, on the one hand, provide protection for the connection between the first function chip 80 and the second rewiring layer 60, preventing corrosion or damage to the connection, and on the other hand, it can improve the bonding performance of the first function chip 80 and the second rewiring layer 60, improving mechanical strength of layer 60, on the other hand it can improve the bonding properties of the first function chip 80 and the second rewiring layer 60 and improve the mechanical strength.

As an example, a heat transfer medium layer 120 is provided between the first function chip 80 and the cooling layer 110, the heat transfer medium layer 120 may be a thermal paste or other highly thermally conductive material, so that on the one hand, the heat transfer medium layer 120 may act as a binder between the first function chip 80 and the cooling layer 110, and on the other hand, heat from the first function chip 80 may be be more efficiently thermally conducted to the cooling layer 110 through the heat transfer medium layer 120.

As an example, the encapsulation wafer comprises an 8-inch or 12-inch encapsulation wafer, specifically, in this embodiment, the encapsulation wafer adopts a 12-inch encapsulation wafer, and the conducting bump 70 is connected to the encapsulation wafer for subsequent electrical lead-in to the encapsulation body, such as connection to an external power supply and the like.

As an example, as shown in FIG. 14, shown as a plan view of a planar layout of the first function chip 80 and the components 90, a plurality of the first function chips 80 and a plurality of the components 90 are arranged in an array, which allows for the integration of a plurality of function chips, including a processor, a memory, etc., and a plurality of components, including photovoltaic components, optical components, MEMS components, etc., in a single encapsulated wafer in a single package in a single encapsulated wafer, thereby realizing a substantially complete function.

Optionally, as shown in FIG. 15, a second function chip 130 and a connector 140 are also included, the second function chip 130 and the connector 140 being connected to the electrically conducting bump 70, respectively.

As an example, the second function chip 130 includes, but is not limited to, a processor, a memory, a power management chip, a transmitter chip, a receiver chip, and the like.

As an example, the second function chip 130 is provided with a second filler layer 150 between the second function chip 130 and the electrically conducting bump 70, the second filler layer 150 can, on the one hand, provide protection for the connection between the second function chip 130 and the electrically conducting bump 70, preventing corrosion or damage to the connection, and, on the other hand, can improve the bonding performance between the second function chip 150 and the electrically conducting bump 70, improving the mechanical strength.

As an example, the connector 140 comprises a header connector, the connector 140 being used to subsequently connect to the encapsulated wafer and thus to an external power supply.

It should be noted that by providing two chip layers (i.e., a first function chip 80 layer area and a second function chip 130 layer area), higher flexibility and wider compatibility are achieved while realizing a high-density sealed connection. For example, realizing the complete function of the package body while setting up two chip layers can improve the spacing between the chips, reduce the crosstalk between the chips, and improve flexibility and compatibility.

In summary, in the fan-out system level packaging structure and production method provided by the present invention, the interconnection of the upper and lower layers is realized through metal connection columns, which can be used for ultra-high-level process system level packaging, and the first function chip and components are connected to the second rewiring layer for high-density connectivity packaging, so that the processor, the memory and other function chips and the optoelectronic components, optical components and MEMS components are integrated into a package body to realize a basic complete function in a single encapsulated wafer (e.g., 8-inch or 12-inch). Optoelectronic components, optical components and MEMS components, etc. can be integrated in a package to achieve a basic complete function, which can improve the integration of the process structure and reduce the size of the package; in addition, the second function chip can be connected to the connector in the conducting bumps, which can realize high-density hermetically-sealed connections with a higher degree of flexibility and a wider range of compatibility, and increase the performance of the package body. Therefore, the present invention effectively overcomes the shortcomings of the prior art and has high industrial utilization value.

The foregoing embodiments are only illustrative of the principles of the present invention and its efficacy and are not intended to limit the invention. Any person skilled in the art may modify or change the above embodiments without violating the spirit and scope of the present invention. Accordingly, all equivalent modifications or alterations accomplished by persons having ordinary knowledge in the art without departing from the spirit and technical ideas disclosed herein shall still be covered by the claims of the present invention.

1. A method of fabricating a fan-out system level packaging structure comprising following steps:
providing a support carrier and forming a separation layer on the support carrier;
forming a first rewiring layer on the separation layer, wherein the first rewiring layer comprises a laminated first dielectric layer and a first metal wiring layer;
forming a metal connecting post on the first rewiring layer, wherein the metal connecting post is electrically connected to the first metal wiring layer;
forming an encapsulation layer over the first rewiring layer, wherein the encapsulation layer covers the first rewiring layer and the metal connecting post, and thinning the encapsulation layer to expose the metal connecting post;
forming a second rewiring layer on the encapsulation layer, wherein the second rewiring layer comprises a stacked second dielectric layer and a second metal wiring layer, wherein the second metal wiring layer is electrically connected to the metal connecting post;
peeling the support carrier at the separation layer to expose a side of the first rewiring layer away from the encapsulation layer;
forming an electrically conducting bump on a side of the first rewiring layer away from the encapsulation layer, wherein the electrically conducting bump is electrically connected to the first rewiring layer;
providing at least one first functional chip with at least one component, and electrically connecting the first functional chip and the component respectively to a side of the second rewiring layer away from the encapsulation layer;
forming a cooling layer on the second rewiring layer, forming a cavity between the cooling layer and the second rewiring layer, and disposing the first function chip and the component in the cavity; and
providing an encapsulated wafer and connecting the conducting bump to the encapsulated wafer.

2. The method of fabricating the fan-out system level packaging structure according to claim 1, prior to forming the metal connecting post, further comprising a step of forming a first opening on a side of the first rewiring layer away from the separator layer, wherein the first opening exposes the first metal wiring layer, wherein the metal connecting post extends into the first opening to connect with the first metal wiring layer.

3. The method of fabricating the fan-out system level packaging structure according to claim 1, wherein forming the conducting bump is preceded by a step of forming a second opening on a side of the first rewiring layer away from the encapsulation layer, wherein the second opening exposes the first metal wiring layer, and wherein the conducting bump extends into the second opening to connect with the first metal wiring layer.

4. The method of fabricating the fan-out system level packaging structure according to claim 1, wherein a plurality of the first function chips is arranged in an array in a horizontal direction; and wherein a plurality of the components is arranged in an array in a horizontal direction.

5. The method of fabricating the fan-out system level packaging structure according to claim 1, wherein the first rewiring layer comprises at least one first dielectric layer and at least one first metal wiring layer stacked in a vertical direction; and wherein the second rewiring layer comprises at least one second dielectric layer and at least one second metal wiring layer stacked in a vertical direction.

6. The method of fabricating the fan-out system level packaging structure according to claim 1, before connecting the conducting bump to the encapsulated wafer, further comprising following steps:
providing at least one second function chip, connecting the second function chip to the conducting bump; and
providing a connector connecting to the conducting bump, and spacing the second functional chip at a predetermined distance from the connector, wherein the conducting bump is connected to the encapsulated wafer through the connector.

7. A fan-out system level packaging structure comprising:
a first rewiring layer, wherein the first rewiring layer comprises a laminated first dielectric layer and a first metal wiring layer;
a second rewiring layer, disposed above the first rewiring layer and spaced at a predetermined distance from the first rewiring layer, wherein the second rewiring layer comprises a second dielectric layer and a second metal wiring layer;
an encapsulation layer disposed between the first rewiring layer and the second rewiring layer;
a metal connecting post, disposed in a vertical direction through the encapsulation layer, wherein a bottom end of the metal connecting post is electrically connected to the first metal wiring layer and a top end of the metal connecting post is electrically connected to the second metal wiring layer;
an electrically conducting bump, disposed below the first rewiring layer and electrically connected to the first rewiring layer;
at least one first function chip, electrically connected to the second rewiring layer;
at least one component, electrically connected to the second rewiring layer, wherein the component is spaced at a predetermined distance from the first functional chip;
a cooling layer, disposed on the second rewiring layer, wherein the cooling layer forms a cavity between the cooling layer and the second rewiring layer, and wherein the first functional chip and the component are disposed in the cavity; and
an encapsulated wafer, disposed on a side of the first rewiring layer having the conducting bump, wherein the encapsulated wafer is connected to the conducting bump.

8. The fan-out system level packaging structure according to claim 7, further comprising a plurality of the first function chips arranged in an array in a horizontal direction and a plurality of the components arranged in an array in the horizontal direction.

9. The fan-out system level package structure according to claim 7, wherein the first dielectric layer and the first metal wiring layer are stacked in a vertical direction; and wherein the second dielectric layer and the second metal wiring layer are stacked in the vertical direction.

10. The fan-out system level packaging structure according to claim 7, further comprising a connector and at least one second function chip disposed between the encapsulated wafer and the conducting bump, wherein the connector connects to the conducting bump, the second function chip connects to the conducting bump, wherein the second function chip is spaced at a predetermined distance from the connector, and wherein the encapsulated wafer connects to the conducting bump via the connector.
